(19) United States
(12) Patent Application Publication
(10) Pub. No.: US 2002/0115283 A1
(43) Pub. Date: Aug. 22, 2002

(54) Planarization by selective electro-dissolution

(75) Inventors: Paul Kwok Keung Ho, Singapore (SG); Mei Sheng Zhou, Singapore (SG); Subhash Gupta, Singapore (SG); Ramasamy Chockalingam, Singapore (SG)

Correspondence Address: GEORGE O. SAILE, 20 MCINTOSH DRIVE, POUGHKEEPSIE, NY, 12603, US

(73) Assignee: Chartered Semiconductor Manufacturing Ltd.

(21) Appl. No.: 09/785,115

(22) Filed: Feb. 20, 2001

(51) Int. Cl. H01L 21/4763

(52) U.S. Cl. 438/633

(57) ABSTRACT

A method is disclosed for removing metal from semiconductor substrates, optionally with or without the use of an abrasive slurry, and the attendant problems of defects caused by mechanical scratches, chemical corrosion and oxidation of components as is normally encountered with the well-known chemical-mechanical polishing (CMP) techniques. The metal removal is accomplished by placing a substrate having the metal layer in an electrolytic system in a tank, and rotating a pad against the substrate while passing current through the system including a cathode and the anodic metal layer. Preferably, the pad size is smaller than that of the substrate. The action of the pad against the metal layer moves an additive in the electrolytic solution from high regions to low regions on the metal layer, thus exposing the high regions to be polished away until all the regions are planarized to molecular height of the additive across the whole metal layer. The method is especially well suited to polishing copper metal layers which experience extensive damage when polished using the conventional, slurry fed CMP techniques.

### BACKGROUND OF THE INVENTION

(1) Field of the Invention

The present invention relates generally to Chemical Mechanical Polish (CMP) planarizing of layers within integrated circuits. More particularly, the present invention relates to an electro-dissolution polish (EDP) planarizing of layers aided by slurry-free mechanical and chemical actions in the manufacture of ultra large scale integrated (ULSI) circuit chips.

(2) Description of the Related Art

The importance of planarization and flatness of the surfaces formed in semiconductor substrates are well recognized in the integrated circuit (IC) industry. Conventionally, etch-back techniques are used to planarize conductive (metal) or non-conductive (insulator) surfaces. However, some important metals, such as gold, silver and copper, which have many desirable characteristics as interconnect materials for integrated circuits, are not readily amenable to etching, and hence, chemical mechanical polishing (CMP), which is well-known in the art, is becoming an even more important process in the manufacture of ultra large scale integrated (ULSI) circuits. In ULSI, more devices are being packed into smaller areas in semiconductor substrates and unconventional metals, such as copper, being used in order to improve the over-all performance of the circuits. More devices in a given area on a substrate require better planarization techniques due to the unevenness of the topography formed by the features themselves, such as metal lines, or the topography of the layers formed over the features. Because many layers of metals and insulators are formed successively one on top of another, each layer need to be planarized to a high degree if higher resolution lithographic processes are to be used to form smaller and higher number of features on a layer in a semiconductor substrate.

A conventional CMP apparatus is shown in FIG. 1. The apparatus includes rotatable polishing platen (10) fixed to rotatable shaft (38), polishing pad (14) mounted on the platen, rotatable workpiece (100), carrier (22) arranged proximate to platen (10) and adapted such that a suitable force (arrow F) is exerted on the workpiece carried within a recess (not shown) of carrier (36). The apparatus further includes a polishing slurry supply system including a reservoir or container (16), conduit (18) in fluid communication with container (16) and pad (14), and chemical polishing slurry (20) held within the container. Slurry (20) is dispensed onto pad (14) via conduit (18). As is well-known in the art, a CMP slurry typically comprises a) aqueous acidic or basic compounds; b)aqueous oxidant compositions; c)non-aqueous liquid halogenated or pseudo halogenated compositions; or d) organic precursor compositions, all, usually accompanied by abrasive particles, such as alumina abrasive powders, silica abrasive powders and titanium abrasive powders.

The prior art apparatus shown in FIG. 1 is used by Uzoh, et al., in U.S. Pat. No. 5,911,619 to disclose a method of planarizing a layer of a workpiece such as a semiconductor wafer. The layer is rotated against an electrolytic polishing slurry and electrical current passed through the slurry and one side of the layer, to remove portions of the layer. The other side carries no microelectronic components which might be damaged by the current. At least a part of each step of rotating and of flowing occurs simultaneously. The workpiece electrodes are movably attached to the carrier so as to engage electrically the sides of a layer when a workpiece is held on the carrier.

Another electrochemical polishing technique is used by Bernhardt, et al., in U.S. Pat. No. 5,256,565 for fabricating planarized thin film metal interconnects for integrated circuit structures where a planarized metal layer is etched back to the underlying dielectric layer by electro polishing or ion milling. The metal layer to be etched back is made the anode in an electric circuit. The metal is placed in an electrolytic bath and an electric current is run through the bath to cause anodic dissolution of the metal layer. The etched back planarized thin film interconnect is flush with the dielectric layer.

A method and apparatus for spatially uniform electropolishing and electrolytic etching are disclosed in U.S. Pat. No. 5,906,550 by Mayer, et al. Here, the anode is separated from the cathode to prevent bubble transport to the anode and to produce a uniform current distribution at the anode by means of a solid nonconducting anode-cathode barrier. The anode extends into the top of the barrier and the cathode is outside the barrier. A virtual cathode hole formed in the bottom of the barrier below the level of the cathode permits current flow while preventing bubble transport. The anode is rotatable and, oriented horizontally facing down. An extended anode is formed by mounting the workpiece in a holder which extends the electropolishing or etching area beyond the edge of the workpiece to reduce edge effects at the workpiece. A reference electrode controls cell voltage. Endpoint detection and current shut-off stop polishing. Spatially uniform polishing or etching is performed.

Still another technique for electrochemical planarizing of surfaces is taught by Datta in U.S. Pat. No. 5,567,300. The process uses a neutral salt solution in a cell. When a potential difference is placed across the cell by the source of voltage, the first electrode surface is electrochemically planarized.

A method for CMP planarizing of copper containing conducting layers is taught by Zhou, et al., in U.S. Pat. No. 5,780,358. There is first provided a semiconductor substrate having formed upon its surface a patterned substrate layer. Formed within and upon the patterned substrate layer is a blanket copper metal layer or a blanket copper metal alloy layer. The blanket copper metal layer or blanket copper metal alloy layer is then planarized through a CMP planarizing method employing a CMP slurry composition. The CMP slurry composition comprises a non-aqueous coordinating solvent and a halogen radical producing specie.

However, prior CMP methods utilize slurry for removal of metal, or methods not using mechanical action. Furthermore, with copper, exceptionally high amounts of slurry needed. Slurry involves abrasive particles and corrosive as well as oxidizing chemicals, which are not desirable. It is shown later in the embodiments of the present invention a method of removing metal using electro-dissolution polishing (EDP) aided by slurry-free mechanical and chemical actions.

### SUMMARY OF THE INVENTION

It is therefore an object of the present invention to provide a method of removing metal from semiconductor substrates without the use of an abrasive slurry, and the attendant problems of defects caused by mechanical scratches, chemical corrosion and oxidation of components in the substrate.

It is another object of this invention to provide a method of removing metal form semiconductor substrates through the use of electro-dissolution polish (EDP) mechanism.

Specifically, it is the object of the present invention to provide a method of removing copper from semiconductor substrates through the use of electro-dissolution polish (EDP) mechanism, obviating the use of an abrasive slurry, and the attendant problems of defects caused by mechanical scratches, chemical corrosion and oxidation of components in the substrate.

These objects are accomplished by providing a semiconductor substrate having a substructure comprising devices formed therein; forming a patterned layer over said substrate; forming within and upon said patterned layer a blanket metal layer; immersing said substrate comprising said blanket metal layer, ₁ₙ an electrolytic system with an additive, in a tank containing a rotatable pad and a cathode; forming an electrical contact with said substrate in said tank to form an anode of said metal layer on said substrate; passing current through said electrolytic system and rotating said pad against said substrate; and performing electro-dissolution polish (EDP) of said blanket metal layer on said substrate.

### BRIEF DESCRIPTION OF THE DRAWINGS

In the drawings that follow, similar numerals are used referring to similar parts throughout the several views.

FIG. 1 is a sketch of a prior art Chemical-Mechanical Polishing (CMP) apparatus.

FIG. 2 is a sketch of a Electro-Dissolution Polishing (EDP) apparatus of the present invention.

FIG. 3a is a partial cross-sectional view of a semiconductor substrate showing the forming of an FET device, according to the present invention.

FIG. 3b is a partial cross-sectional view of the semiconductor substrate of FIG. 3a showing the forming of contacts to an FET device, according to the present invention.

FIG. 3c is a partial cross-sectional view of the semiconductor substrate of FIG. 3b showing the forming of a metal interconnect layer and the action of the additives admixed with the electrolytic solution of the present invention.

FIG. 3d is a partial cross-sectional view of the semiconductor substrate of FIG. 3c showing the stripping off of the additive molecules from elevated regions of the substrate through the mechanical action of a pad, according to the present invention.

FIG. 3e is a partial cross-sectional view of the semiconductor substrate of FIG. 3d showing the planarization of a metal layer, according to the present invention.

FIG. 3f is a partial cross-sectional view of the semiconductor substrate of FIG. 3e showing the completion of the forming of a metal interconnect through the use of the disclosed EDP method of the present invention.

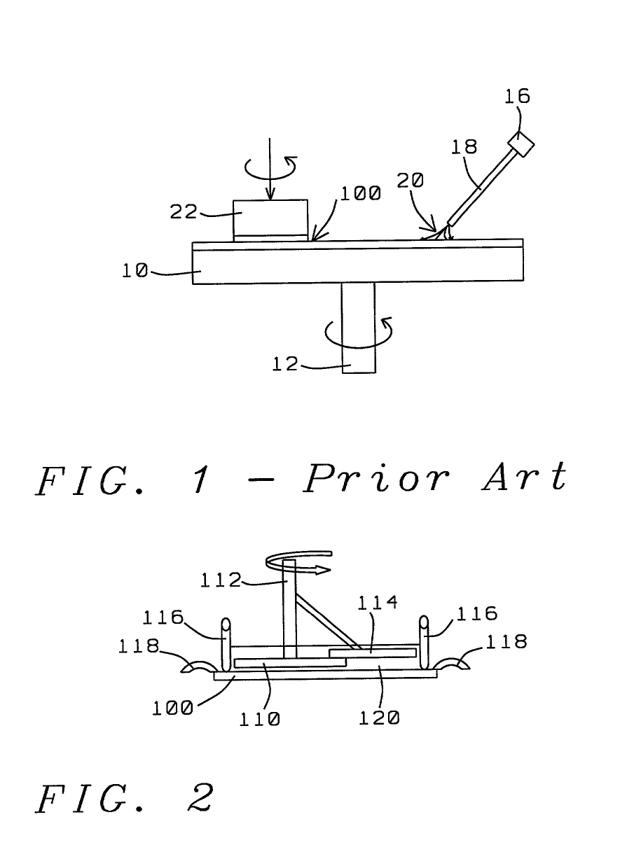

### DESCRIPTION OF THE PREFERRED EMBODIMENTS

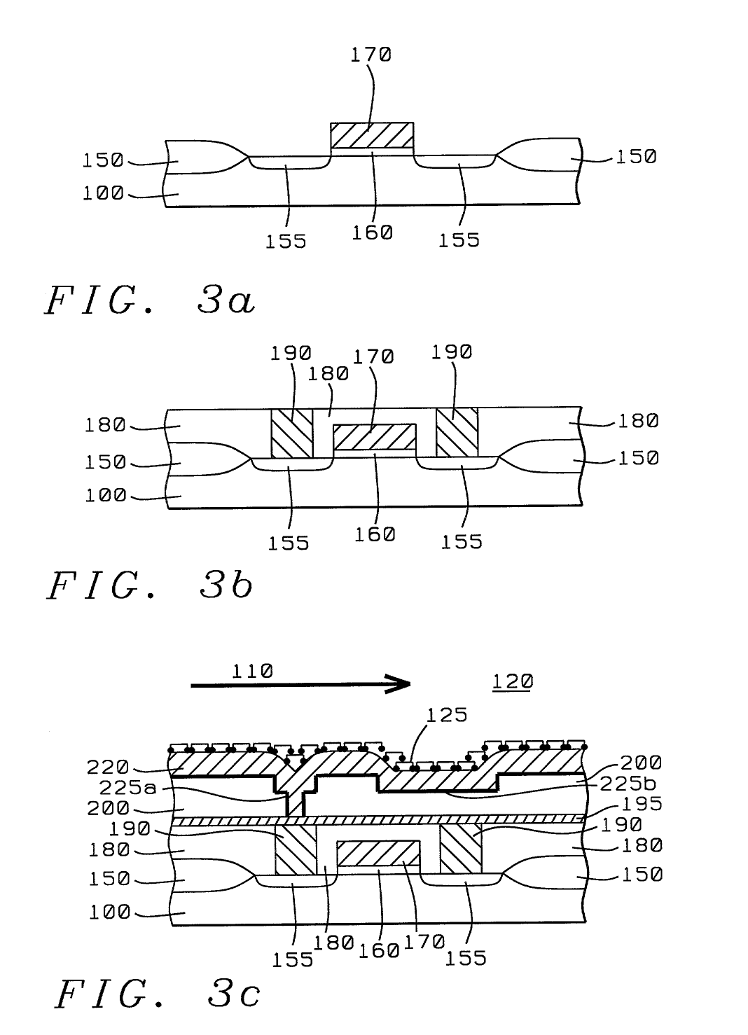

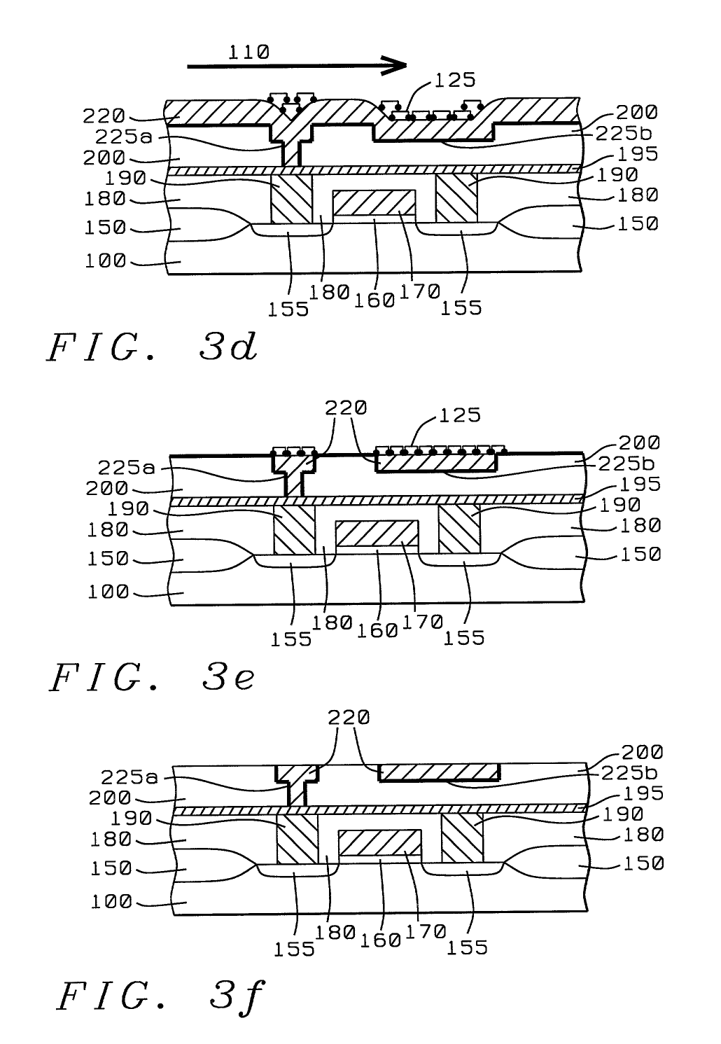

Referring now to the drawings, in particular to FIG. 2, and FIGS. 3a-3e, there is shown a method of removing metal from a semiconductor substrate without the use of an abrasive slurry, and the attendant problems of defects caused by mechanical scratches, chemical corrosion and oxidation of components as is normally encountered with the well-known chemical-mechanical polishing (CMP) techniques. The method is preferred especially for polishing copper metal layer which would normally experience extensive damage when polished using conventional, slurry fed CMP techniques.

Specifically, FIG. 2 shows an apparatus for removing metal from a metal layer of irregular surface so as to planarize that surface through the use of an Electro-Dissolution Polish (EDP) mechanism assisted by the mechanical action of a rotating pad. The apparatus comprises a container, or a tank placed over a substrate, or wafer (100), and sealed against the surface of the substrate by means of seals (116). The container is next filled with electrolytic solution (120) with a key additive disclosed below, but with no abrasive materials. A rotatable shaft, (112), attached to pad (110) having cathode (114) is next lowered over the wafer inside the container, as shown in the same container. The substrate is then planarized in the apparatus shown as is further described in the preferred embodiments of the present invention:

Referring now to FIGS. 3-a to 3-e, there is shown a series of schematic cross-sectional views illustrating progressive stages in forming several Electro-Dissolution Polish (EDP) planarized copper metal or copper metal alloy layers within an integrated circuit through the EDP planarizing method of the preferred embodiment of the present invention. In FIG. 3a, substrate (100) is shown where isolation regions (150) are formed using conventional techniques. Semiconductor substrates upon which the present invention may be practiced may be formed with either dopant polarity, any dopant concentration and any crystallographic orientation. Typically, semiconductor substrate (100), upon which the present invention may be practiced is a N- or P-silicon semiconductor substrate having a 100-crystallographic orientation.

Methods by which isolation regions may be formed within and upon semiconductor substrates are known in the art, including LOCOS (Local Oxidation of Silicon), and STI (Shallow Trench Isolation), where usually the latter method is preferred. In FIG. 3a, isolation regions (150) are formed through a thermal oxidation process whereby portions of semiconductor substrate (100) exposed through an oxidation mask are consumed to form within and upon the semiconductor substrate isolation regions (150) of silicon oxide.

Also illustrated within FIG. 3a is gate oxide layer (160) upon which resides gate electrode (170). Both the gate oxide layer and the gate electrode reside upon the active semiconductor region of semiconductor substrate (100). Both gate oxide layer (160) and gate electrode (170) are components of a Field Effect Transistor (FET) as it will be recognized by those skilled in the art. Methods and materials through which gate oxide layers and gate electrodes may be formed upon active semiconductor regions of semiconductor substrates are known in the art.

There are also shown in FIG. 3a source/drain electrodes (155) formed within the surface of the active semiconductor region of semiconductor substrate (100) at areas not occupied by gate electrode (170), gate oxide layer (160) and isolation regions (150). Methods and materials through which source/drain electrodes may be formed within semiconductor substrates are known in the art, and will not be described in detail here so as to not obscure the key aspects of the present invention.

Having thus formed a Field Effect Transistor (FET) structure comprising source/drain electrodes (155) formed into semiconductor substrate (100), and gate electrode (170) upon gate oxide layer (160) adjoining source/drain electrodes (155), contacts (190) are made to the FET device as shown in FIG. 3b. These metal contacts may be made by using conventional techniques of forming and patterning a dielectric layer (180), depositing metal, removing excess metal (not shown) in any number of ways, such as employing CMP, and so on; however, the disclosed next series of process steps, including the EDP method, are preferred as they provide much improved, and damage free metal interconnects within semiconductor devices.

The next series of process steps involve forming various metal layers to interconnect the various devices and circuits that have been already formed on the substrate. The metal layers are separated from each other by dielectric layers. The first dielectric layer that separates the device containing substrate from the first interconnect layer is commonly referred to as the Inter-Level Dielectric (ILD) layer, while the subsequently formed dielectric layers that separate the additional metal layers as Inter-Metal Dielectric (IMD) layers. Accordingly, dielectric layer (180) in FIG. 3b is known as an ILD layer, while dielectric layer (200) formed over the ILD layer, as shown in FIG. 3c, is known as an, or, first, IMD layer if there are more layers to be formed on the substrate.

Shown in both FIGS. 3b and 3c are patterned dielectric layers, namely, ILD and IMD layers, respectively. The patterns are filled with metal. Methods and materials through which patterned dielectric layers may be formed within integrated circuits are known in the art. Patterned layers are typically, although not exclusively, formed through patterning through methods as are conventional in the art of blanket Inter-Level Dielectric layers. The patterning may be accomplished through photolithographic and etch methods as are conventional in the art, including but not limited to wet chemical etch methods and Reactive Ion Etch (RIE) etch methods. The blanket dielectric layers may be formed through methods and materials including but not limited to Chemical Vapor Deposition (CVD) methods. Plasma Enhanced Chemical Vapor Deposition (PECVD) methods and Physical Vapor Deposition (PVD) sputtering methods through which may be formed blanket ILD layers of dielectric materials including but not limited to silicon oxide dielectric materials, silicon nitride dielectric materials and silicon oxynitride dielectric materials. Spin-on method is also used to deposit low-k dielectric materials.

For the preferred embodiment of the present invention, the patterned ILD and IMD layers (180) and (200), respectively, are preferably formed through patterning via an RIE etch method as is common in the art of a blanket ILD layer formed of a silicon oxide deposited through a PECVD method, as is also common in the art. The thickness of the patterned dielectric layers will depend upon the type of structures that are formed in them. It will be apparent to those skilled in the art that pattern (225a) shown in FIG. 3c is a dual damascene structure having an upper trench layer with a thickness between about 2000 to 8000 Å, and a lower via layer with a thickness between about 3000 to 8000 Å, while pattern (225b) is a single damascene structure for a line interconnect. As is seen in FIG. 3c, IMD layer (200) is formed over a first metal layer, i.e., layer (195), which contacts dual damascene structure (225a). The patterns formed within IMD layer (200) have been filled with blanket metal layer (220), and there is excess metal that needs to be removed, and the substrate surface planarized for reasons well known in the art.

As any conductor material to be used in a multilevel interconnect has to satisfy certain essential requirements such as low resistivity, resistance to electromigration, adhesion to the underlying substrate material, stability (both electrical and mechanical) as ease of processing. Copper is often preferred due to its low resistivity, high electromigration resistance and stress voiding resistance. Copper unfortunately suffers from high diffusivity in common insulating materials such as silicon oxide and oxygen-containing polymers, and other materials used for STI. For instance, copper tends to diffuse into polyimide during high temperature processing of the polyimide. This causes severe corrosion of the copper and the polyimide due to the copper combining with oxygen in the polyimide. The corrosion may result in loss of adhesion, delamination, voids, and ultimately a catastrophic failure of the component. Diffusion will also cause metal to metal leakage. A copper diffusion barrier layer is therefore often required, and is usually selected from a group consisting of titanium, tungsten, tantalum, and compounds and combinations thereof. Such a barrier layer is shown with reference numeral (210) in FIG. 3b, having, preferably, a thickness between about 50 to 500 Å.

The blanket copper containing conductor layer (220) may be formed of copper metal or a copper metal alloy. Preferably, layer (220) contains at least about 80 percent copper. Preferably, the thickness of the blanket copper containing conductor layer (220) is between about 3000 to 15000 Å. As it will be understood by those skilled in the art, the blanket copper containing conductor layer (200) may be formed through deposition methods conventional to the art, including but not limited to thermally assisted deposition methods, electron beam assisted deposition methods, PVD sputtering methods and CVD methods.

Referring again to FIG. 3c, substrate, or wafer (100) with excess copper metal (220), is shown to have been placed in the tank of FIG. 2 containing electrolytic solution (120), for the purposes of removing the excess metal, and at the same time, planarizing and polishing the metal surface without incurring any damage, which is the object of the present invention. This is accomplished by employing the Electro-Dissolution Polish (EDP) method. A main feature and key aspect of the invention is the use of an electrolytic system which contains an additive that provides selective and topography sensitive, rather than global—as in the case of CMP—removal of metal with mechanical assistance, and without the use of any abrasive slurry that is commonly used with CMP. In FIG. 3c, substrate (100) is placed in electrolytic solution (120), and additive (125) is shown to adhere to copper surface. Once the current is passed through the system, with Cu layer (220) rendered anodic, and pad (110) starts rotating, the pad starts whipping off the additive on the elevated regions, such as reference (227) in FIG. 3d, on the substrate. It will be appreciated by those skilled in the art that though an electrolytic solution by itself will cause electro-dissolution of the metal, the presence of the additive causes much higher current density differential between the elevated and lower regions, and hence the metal removal is accelerated considerably. That is, the action of the pad through interaction with the additive molecules causes a significant differential in strip rate between the elevated and recess areas and brings about planarization much more rapidly. The pad movement also aids in the removal of copper ions at the vicinity of elevated regions to facilitate the continuous removal of copper.

The electrolytic system, shown by reference numeral (120) in FIGS. 2 and 3c, can be an aqueous solution of a simple salt, such as, but not limited to, (NH₄)₂SO₄, or an aqueous acid mixture, such as, but not limited to, H₃PO₄, or can be a mixture of the above. The main feature of the present invention, namely, the additive, is first admixed with the electrolytic solution. The additive can be, but not limited to, benzotriazole (BTA), benzotriazole derivatives. It is also important that pad (110) shown in FIG. 2 has a circular dimension smaller than the overall dimension of wafer (100) so that the rotational motion will force the electrolytic solution in and out of the gap between the pad and the surface of the metal layer on the substrate. It will also be appreciated that the force transmitted to the wafer via the pad can be varied through shaft (112) in order to influence the metal removal from the substrate.

After the planarization of the metal surface, barrier layer (210) shown in FIG. 3e can be removed by using a dry etch method, such as chlorine plasma dry etching or fluorine plasma dry etching. Substrate (100) can then be readied for further process steps as shown in FIG. 3f. Alternately, barrier layer (210) can be removed by a conventional defect-removal buffing CMP.

Though these numerous details of the disclosed method are set forth here, such as process parameters, to provide an understanding of the present invention, it will be obvious, however, to those skilled in the art that these specific details need not be employed to practice the present invention. Also, the apparatus described in FIG. 2 is used to explain but not limit the extendibility of the method.

That is to say, while the invention has been particularly shown and described with reference to the preferred embodiments thereof, it will be understood by those skilled in the art that various changes in form and details may be made without departing from the spirit and scope of the invention.

What is claimed is:

1. A method of planarization by selective electro-dissolution comprising the steps of:
providing a semiconductor substrate having a substructure comprising devices formed therein;
forming a patterned layer over said substrate;
forming within and upon said patterned layer a blanket metal layer;
immersing said substrate comprising said blanket metal layer, in an electrolytic system with an additive, in a tank containing a rotatable pad and a cathode;
forming an electrical contact with said substrate in said tank to form an anode of said metal layer on said substrate;
passing current through said electrolytic system and rotating said pad against said substrate; and
performing electro-dissolution polish (EDP) of said blanket metal layer on said substrate.

2. The method of claim 1, wherein said patterned layer is a dielectric layer.

3. The method of claim 2, wherein said patterned dielectric layer contains a single or a dual damascene structure with a trench layer between about 2000 to 8000 Å, and a via layer between about 3000 to 8000 Å.

4. The method of claim 1, wherein said blanket metal layer further comprises at least 80% copper.

5. The method of claim 1, wherein said metal layer has a thickness between about 3000 to 15000 Å.

6. The method of claim 1, wherein said electrolytic system comprises phosphoric acid/sulphuric acid mixture or other salts such as ammonium sulphate.

7. The method of claim 1, wherein said additive comprises benzotriazole (BTA) or BTA derivatives.

8. The method of claim 1, wherein said rotatable pad has a circular dimension smaller than said substrate in said tank;

9. The method of claim 1, wherein said performing said EDP is accomplished optionally with or without the use of any abrasive slurry in said electrolytic system.

10. A method of planarization by selective electro-dissolution comprising the steps of:
providing a substrate having a metal layer formed thereon;
immersing said substrate having said metal layer in an electrolytic system with an additive, ᵢₙ a tank containing a rotatable pad and a cathode;
passing current through said electrolytic system and rotating said pad against said substrate; and
performing electro-dissolution polish (EDP) of said blanket metal layer on said substrate.

11. The method of claim 10, wherein said blanket metal layer further comprises at least 80% copper.

12. The method of claim 10, wherein said metal layer has a thickness between about 3000 to 15000 Å.

13. The method of claim 10, wherein said electrolytic system comprises phosphoric acid/sulphuric acid mixture or other salts such as ammonium sulphate.

14. The method of claim 10, wherein said additive comprises BTA or BTA derivatives.

15. The method of claim 10, wherein said rotatable pad has a circular dimension smaller than said substrate in said tank;

16. The method of claim 10, wherein said performing said EDP is accomplished optionally with or without the use of any abrasive slurry in said electrolytic system.
